(19) United States
(12) Patent Application Publication
(10) Pub. No.: US 2018/0301605 A1
(43) Pub. Date: Oct. 18, 2018

(54) A WINDOW THAT COVERS AN OPTOELECTRONIC SEMICONDUCTOR CHIP, A PANEL COMPRISING A PLURALITY OF WINDOWS, A METHOD OF PRODUCING WINDOWS AND AN OPTOELECTRONIC SEMICONDUCTOR DEVICE

(71) Applicant: OSRAM Opto Semiconductors GmbH, Regensburg (DE)

(72) Inventors: Sok Gek Beh, Gelugor (MY); Eng Suan Neoh, Batu Maung (MY); Sung Ern Kow, Tanjung Bungah (MY)

(21) Appl. No.: 15/559,684

(22) PCT Filed: Mar. 19, 2015
(86) PCT No.: PCT/EP2015/055833

§ 371 Date: Sep. 19, 2017

(51) Int. Cl. H01L 33/58

(52) U.S. Cl. CPC H01L 33/58

(57) ABSTRACT

A window that covers an optoelectronic semiconductor chip includes an upper face, the upper face including a polygonal shape, wherein at least one corner of the upper face is chamfered. A method of producing a window that covers an optoelectronic semiconductor chip, the method including providing a panel; creating a plurality of holes at an upper face of the panel; dividing the panel along separation lines to obtain a plurality of windows, wherein the separation lines extend through the holes.

### TECHNICAL FIELD

This disclosure relates to a window that covers an optoelectronic semiconductor chip, an optoelectronic semiconductor device, a panel and a method for producing a window.

### BACKGROUND

Optoelectronic semiconductor devices comprising a glass window covering one or more optoelectronic semiconductor chips are known. Such windows are easily damageable.

### SUMMARY

We provide a window that covers an optoelectronic semiconductor chip including an upper face, the upper face comprising a polygonal shape, wherein at least one corner the upper face is chamfered.

We also provide an optoelectronic semiconductor device including an optoelectronic semiconductor chip and the window, wherein the window covers the optoelectronic semiconductor chip.

We further provide a panel dividable along separation lines into a plurality of windows that covers optoelectronic semiconductor chips, wherein an upper face of the panel included a plurality of holes arranged on the separation lines.

We still further provide a method of producing a window that covers an optoelectronic semiconductor chip, the method including providing a panel; creating a plurality of holes at an upper face of the panel; dividing the panel along separation lines to obtain a plurality of windows, wherein the separation lines extend through the holes.

### BRIEF DESCRIPTION OF THE DRAWINGS

FIG. 1 shows a schematic perspective view of a window.

FIG. 2 shows a schematic transparent top view of the window.

FIG. 3 shows a sectional side view of an optoelectronic semiconductor device comprising the window.

FIG. 4 shows a schematic transparent top view of a panel.

FIG. 5 shows a schematic top view of a hole arranged at an upper face of the panel.

FIG. 6 shows a schematic sectional side view of the panel.

### REFERENCE NUMBERS

100 window

101 upper face

102 lower face

110 corner

120 chamfer

121 depth

122 length

130 recess

200 optoelectronic semiconductor device

210 optoelectronic semiconductor chip

220 carrier

300 panel

301 upper face

302 lower face

310 separation line

315 intersection

320 hole

321 depth

330 opening

340 corner

341 distance

### DETAILED DESCRIPTION

Our windows that cover an optoelectronic semiconductor chip comprise an upper face, the upper face comprising a polygonal shape. At least one of the corners of the upper face is chamfered.

The chamfer at the corner of the upper face of the window advantageously reduces a risk of damage of the window. Sharp corners are particularly vulnerable to chipping. Chamfering the corner considerably reduces the risk. This reduces the risk of a degradation of optical properties of the window and the risk of potential problems during handling of the window. The reduced risk of damage of the window may result in an increased yield in the production of such windows and a production of optoelectronic semiconductor devices comprising the windows.

The upper face may comprise a rectangular shape. Advantageously, this allows the window to be used to produce an optoelectronic semiconductor device comprising a rectangular shape.

All corners of the upper face may be chamfered. Advantageously, this reduces the risk of damage at all corners of the upper face of the window.

The window may comprise a recess that receives an optoelectronic semiconductor chip at a lower face of the window. Advantageously, this allows the window to partially or fully enclose an optoelectronic semiconductor chip, providing a protective cover for the optoelectronic semiconductor chip.

The window may comprise glass. Advantageously, this allows the window to comprise a high optical transparency. Furthermore, this allows for a cost-efficient production of the window.

An optoelectronic semiconductor device comprises an optoelectronic semiconductor chip and a window of the aforementioned kind. The window covers the optoelectronic semiconductor chip.

Advantageously, the window of the optoelectronic semiconductor device provides protection for the optoelectronic semiconductor chip. The chamfer at the corner of the upper face of the window reduces the risk of the window getting damaged.

A panel designed to be divided along separation lines into a plurality of windows that covers optoelectronic semiconductor chips comprises an upper face. The upper face of the panel comprises a plurality of holes arranged on the separation lines.

Advantageously, the holes arranged on the separation lines at the upper face of the panel automatically create chamfers at corners of the upper faces of the windows when the panel is separated into the windows along the separation lines. The chamfers at the corners of the windows reduce the risk of the windows being damaged.

Each hole may be arranged at an intersection of two separation lines. At the intersection of separation lines, corners of the windows are formed when the panel is divided into the windows along the separation lines. Advantageously, a hole arranged at an intersection of two separation lines may simultaneously create chamfers at several windows adjoining the intersection of the two separation lines when the panel is divided into the windows along the separation lines.

Each hole may comprise a pyramidal shape. Advantageously, a pyramidal shape of a hole may comprise a flat face oriented towards each window adjoining the hole, allowing for a creation of flat chamfers.

Each hole may comprise a depth of 100 μm to 80% of a thickness of the panel. Advantageously, holes of this depth have proven to create chamfers that can remarkably reduce the risk of a damage to a window.

The holes may be arranged in a rectangular grid pattern. Each hole comprises a rectangular opening at the upper face of the panel. The four corners of each opening of each hole are oriented towards the four nearest neighboring holes of the respective hole. Advantageously this panel facilitates creating rectangular windows with rectangular upper faces with chamfers at each corner of each upper face.

Two opposing corners of the opening of each hole may be spaced apart by 300 μm to 1000 μm. Advantageously, holes of such diameter can create chamfers that remarkably reduce the risk of the window being damaged.

A method of producing a window that covers an optoelectronic semiconductor chip comprises steps of providing a panel, creating a plurality of holes at an upper face of the panel, and dividing the panel along separation lines to obtain a plurality of windows. The separation lines extend through the holes.

This method facilitates producing windows comprising chamfers at their upper faces. The chamfers may reduce the risk of the windows being damaged by chipping. The reduced risk of the windows being damaged may increase the yield of the method of producing windows.

Two separation lines may intersect at the position of each hole. Advantageously, this results in chamfers being created at corners of the upper faces of the windows.

The holes are created by etching. Advantageously, this allows for a simple and cost-efficient creation of the holes. A particular advantage of the method is that a plurality of holes can be created simultaneously.

The panel may be divided by sawing. Advantageously, this allows for an easy and cost-efficient division of the panel.

The accompanying drawings are included to provide further understanding and are incorporated into and constitute a part of the specification. The drawings illustrate examples and together with the description serve to explain selected principles. Other examples and many of the intended advantages will be readily appreciated as they will be better understood by reference to the following detailed description. The elements of the drawings are not to scale with regard to each other.

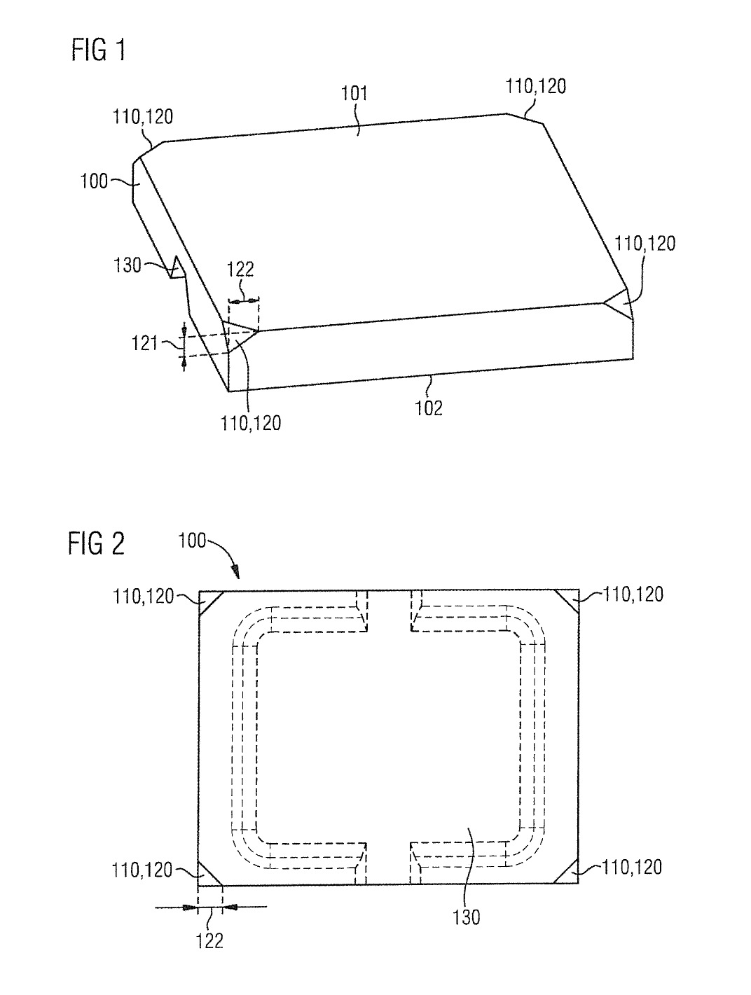

FIG. 1 shows a schematic perspective view of a window 100. The window 100 is designed to cover an optoelectronic semiconductor chip of an optoelectronic device. FIG. 2 shows a schematic transparent top view of the window 100.

The window 100 comprises an optically transparent material. The window 100 may, for example, comprise a glass or a plastic material.

The window 100 comprises an upper face 101 and an opposed lower face 102. The upper face 101 and the lower face 102 each comprise a rectangular shape. In other examples, however, the upper face 101 and the lower face 102 may comprise a triangular or another polygonal shape.

The rectangular upper face 101 comprises four corners 110. Each of the four corners 110 comprises a chamfer 120 such that the tip of the respective corner 110 is removed. Each of the chamfers 120 is arranged at an angle with respect to the upper face 101 of the window 100.

In alternative examples of the window 100, chamfers 120 are arranged at only one, two or three corners 110 of the upper face 101.

The chamfers 120 protect the corners 110 of the window 100 against accidental and uncontrolled chipping of the corners 110 which might damage the window 100.

Each chamfer 120 comprises a depth 121 measured from the upper face 101 in a direction perpendicular to the upper face 101. The depth 121 may, for example, be 100 μm to 80% of the thickness of the windows 100.

Each chamfer 120 comprises a length 122 measured from the removed tip of the respective corner 110 of the window 100 along an edge of the upper face 101. The length 122 may, for example, be 150 μm to 500 μm.

The window 100 comprises a recess 130 at the lower face 102. The recess 130 receives an optoelectronic semiconductor chip of an optoelectronic device. Alternatively, the recess 130 may be omitted.

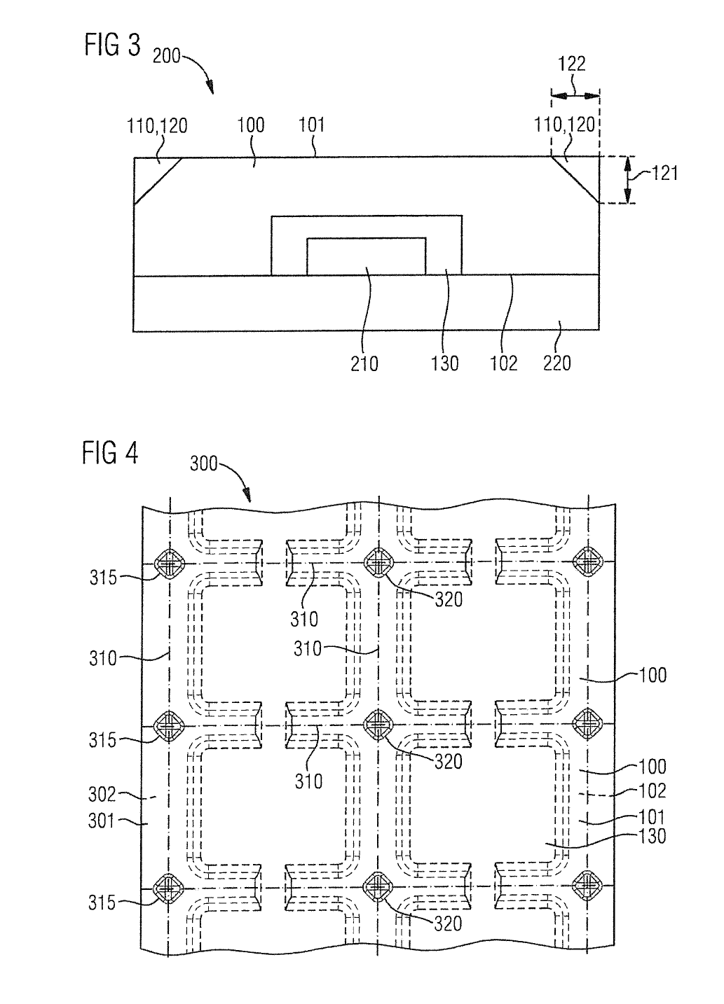

FIG. 3 shows a schematic sectional drawing of an optoelectronic semiconductor device 200. The optoelectronic semiconductor device 200 may be a light emitting device.

The optoelectronic semiconductor device 200 comprises a carrier 220 and an optoelectronic semiconductor chip 210 arranged on the carrier 220. The optoelectronic semiconductor chip 210 may be designed to emit electromagnetic radiation, for example, visible light. The optoelectronic semiconductor chip 210 may be a light emitting diode (LED) chip.

The optoelectronic semiconductor device 200 furthermore comprises the window 100 described above with reference to FIGS. 1 and 2. The window 100 is arranged on the carrier 220 such that the lower face 102 of the window 100 is oriented towards the carrier 220. The optoelectronic semiconductor chip 210 of the optoelectronic semiconductor device 200 is arranged in the recess 130 of the window 100. Consequently, the window 100 covers the optoelectronic semiconductor chip 210 of the optoelectronic semiconductor device 200. An air gap may be arranged between the optoelectronic semiconductor chip 210 and the window 100.

FIG. 4 shows a schematic transparent top view of a part of a panel 300. The panel 300 is a semifinished product for the production of a plurality of windows 100. The panel 300 is designed to be divided into a plurality of windows 100 along separation lines 310. The panel 300 can, for example, be divided along the separation lines 310 by sawing.

The panel 300 comprises an optically transparent material, for example, a glass or a plastic material.

The panel 300 comprises an upper face 301 and an opposed lower face 302. The upper faces 101 of the windows 100 formed out of the panel 300 are formed out of the upper face 301 of the panel 300. The lower faces 102 of the windows 100 formed out of the panel 300 are formed out of the lower face 302 of the panel 300.

In the panel 300, the rectangular windows 100 are arranged in a rectangular grid pattern and integrally connected. If the upper faces 101 of the windows 100 are not rectangular, the windows 100 may be arranged in another regular pattern in the panel 300.

The separation lines 310, along which the panel 300 will be divided into the individual windows 100, are straight lines. The separation lines 310 intersect at intersections 315. In the example depicted in FIG. 4, the separation lines 310 intersect at right angles at the intersections 315.

When the panel 300 is divided into the windows 100 along the separation lines 310, the corners 110 of the windows 100 are formed at the intersections 315 of the separation lines 310.

The upper face 301 of the panel 300 comprises a plurality of holes 320 arranged on the separation lines 310. Each hole 320 is arranged at an intersection 315 of two separation lines 310. Consequently, the holes 320 are arranged in a rectangular grid pattern in the example depicted in FIG. 4.

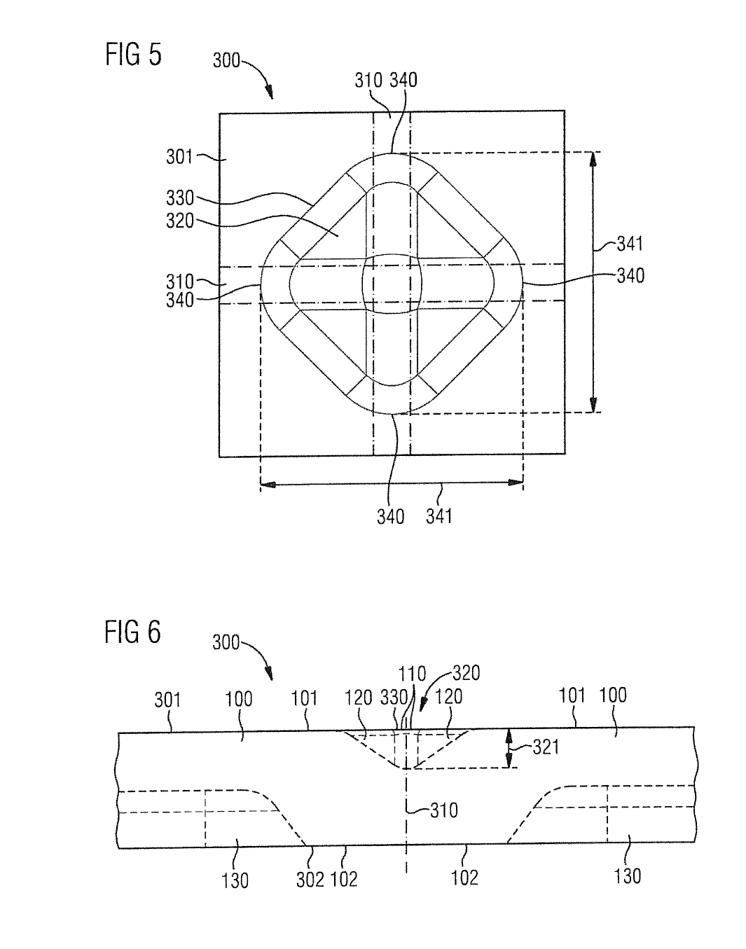

FIG. 5 shows a schematic magnified top view of one hole 320 arranged at the upper face 301 of the panel 300. FIG. 6 shows a schematic sectional drawing of one of the holes 320 arranged at the upper face 301 of the panel 300.

Each hole 320 comprises an opening 330 at the upper face 301 of the panel 300. Each hole 320 extends into the panel 300 by a depth 321, measured in a direction perpendicular to the upper face 301 of the panel 300. The depth 321 may, for example, be 100 μm to 80% of the thickness of the panel 300.

The openings 330 of the holes 320 comprise a rectangular shape with four corners 340. The corners 340 and the edges of the openings 330 of the holes 320 may be rounded due to manufacturing tolerances.

The four corners 340 of each opening 330 of each hole 320 are oriented towards the four nearest neighboring holes 320 of the respective hole 320. This means that the corners 340 of the openings 330 of the holes 320 are arranged on the separation lines 310.

Each two opposing corners 340 of the opening 330 of each hole 320 are spaced apart by a distance 341 which may, for example, be 300 μm to 1000 μm.

In other examples, the openings 330 of the holes 320 may comprise other shapes than rectangular shapes. If the upper faces 101 of the windows 100 comprise a triangular shape, the openings 330 of the holes 320 may, for example, also comprise triangular shapes.

The holes 320 arranged at the upper face 301 of the panel 300 comprise pyramidal shapes. Each hole 320 narrows from its opening 330 at the upper face 301 of the panel 300 towards a single point arranged at the bottom of the respective hole 320 inside the panel 300. The pyramidal shapes of the holes 320 may be rounded due to manufacturing tolerances.

To produce a window 100 as depicted in FIG. 1, first, the panel 300 is provided without the holes 320 at the upper face 301.

In a consecutive step, the holes 320 are created at the upper face 301 of the panel 300. The holes 320 may, for example, be created by etching.

Afterwards, the panel 300 is divided along the separation lines 310 to obtain a plurality of windows 100. The panel 300 may, for example, be divided by sawing.

The separation lines 310 along which the panel 300 is divided extend through the holes 320. Since each hole 320 is arranged at an intersection 315 of two separation lines 310, each hole 320 is divided into four parts upon dividing the panel 300. Each of the faces of each hole 320 forms one chamfer 120 at one corner 110 of one of the windows 100 adjoining the intersection 315 at which the respective hole 320 is arranged.

While our windows, panels, devices and methods have been described in detail with reference to specific examples thereof, it will be apparent to one skilled in the art that various changes and modifications can be made therein without departing from the spirit and scope thereof. Accordingly, this disclosure covers the modifications and variations provided they come within the scope of the appended claims and their equivalents.

1.-16. (canceled)

17. A window that covers an optoelectronic semiconductor chip comprising an upper face, the upper face comprising a polygonal shape, wherein at least one corner of the upper face is chamfered.

18. The window of claim 17, wherein the upper face comprises a rectangular shape.

19. The window of claim 17, wherein all corners of the upper face are chamfered.

20. The window of claim 17, wherein the window comprises a recess that receives an optoelectronic semiconductor chip at a lower face.

21. The window of claim 17, wherein the window comprises a glass.

22. An optoelectronic semiconductor device comprising an optoelectronic semiconductor chip and the window according to claim 17, wherein the window covers the optoelectronic semiconductor chip.

23. A panel dividable along separation lines into a plurality of windows that covers optoelectronic semiconductor chips, wherein an upper face of the panel comprises a plurality of holes arranged on the separation lines.

24. The panel of claim 23, wherein each hole is arranged at an intersection of two separation lines.

25. The panel of claim 23, wherein each hole comprises a pyramidal shape.

26. The panel of claim 23, wherein each hole comprises a depth of 100 μm to 80% of a thickness of the panel.

27. The panel of claim 23, wherein the holes are arranged in a rectangular grid pattern, each hole comprises a rectangular opening at the upper face of the panel, and four corners of each opening of each hole are oriented towards four nearest neighboring holes of the respective hole.

28. The panel of claim 27, wherein two opposing corners of the opening of each hole are spaced apart by 300 μm to 1000 μm.

29. A method of producing a window that covers an optoelectronic semiconductor chip, the method comprising:
providing a panel;
creating a plurality of holes at an upper face of the panel; and
dividing the panel along separation lines to obtain a plurality of windows, wherein the separation lines extend through the holes.

30. The method of claim 29, wherein at the position of each hole two separation lines intersect.

31. The method of claim 29, wherein the holes are created by etching.

32. The method of claim 29, wherein the panel is divided by sawing.
